(19) United States
(12) Patent Application Publication
(10) Pub. No.: US 2010/0221896 A1
(43) Pub. Date: Sep. 2, 2010

(54) Electrical Device with Improved Electrode Surface

(76) Inventor: Regino Sandoval, Rochester Hills, MI (US)

Correspondence Address: Kevin L. Bray;OVONYX, INC, 2956 Waterview Drive, Rochester Hills, MI, 48309, US

(21) Appl. No.: 12/781,362

(22) Filed: May 17, 2010

Related U.S. Application Data
(63) Continuation-in-part of application No. 12/154,952, filed on May 28, 2008.

(51) Int. Cl. H01L 21/20; H01L 21/28

(52) U.S. Cl. 438/478; 257/E21.158; 257/E21.09

(57) ABSTRACT

An electronic device having a reduced-roughness electrode surface. The device includes an active material that forms an interface with a treated electrode surface. Treatment of the electrode surface reduces the roughness of the surface to promote adhesion, conformality, and/or electrical contact of the active material to the electrode. The reduced-roughness electrode surface facilitates the formation of a regular, uniform interface with the active material and minimizes the formation of interfacial voids and/or localized contact points that compromise device performance or endurance. Active materials include variable resistance materials and electrical switching materials.

### CROSS-REFERENCE TO RELATED APPLICATIONS

This application is a continuation in part of U.S. patent application Ser. No. 12/154,952, entitled “Method for Manufacturing Chalcogenide Devices”, and filed on May 28, 2008, the disclosure of which is incorporated by reference herein.

### FIELD OF INVENTION

This invention relates to electrical devices having improved contact between the active material and an electrode. More particularly, this invention relates to electrical memory and switching devices having a smoothed electrode surface. Most particularly, this invention relates to electrical memory and switching devices having an active material disposed within a pore and in direct contact with a smooth electrode surface.

### BACKGROUND OF THE INVENTION

Chalcogenide materials are an emerging class of commercial electronic materials that exhibit switching, memory, logic, and processing functionality. Early work in chalcogenide devices demonstrated electrical switching behavior in which switching from a resistive state to a conductive state was induced upon application of a voltage at or above the threshold voltage of the active chalcogenide material. This effect is the basis of the Ovonic Threshold Switch (OTS) and remains an important practical feature of chalcogenide materials. The OTS provides highly reproducible switching at ultrafast switching speeds for over 10¹³ cycles. Basic principles and operational features of the OTS are presented, for example, in U.S. Pat. Nos. 3,271,591; 5,543,737; 5,694,146; and 5,757,446; the disclosures of which are hereby incorporated by reference.

Another important application of chalcogenide materials is as variable resistance materials for next-generation electronic storage and computing devices. A variable resistance material is a material that possesses two or more states that differ in electrical resistance. The material can be programmed back and forth between the states by providing energy to induce an internal chemical, electronic, or physical transformation of the material that manifests itself as a change in resistance of the material. The different resistance states are distinguishable and can be used as memory states to store or process data. Variable resistance materials offer the benefit of non-volatile performance.

One group of chalcogenide materials is capable of adopting any of several states that span a wide range of resistance values. Each resistance value corresponds to a distinct structural state of the chalcogenide material and one or more of the states can be selected and used to define operational memory states. The distinct structural states may be distinguished on the basis of, for example, crystal structure, atomic arrangement, order or disorder, fractional crystallinity, relative proportions of two or more different structural states, or a physical (e.g. electrical, optical, magnetic, mechanical) or chemical property.

In a common embodiment, the two or more distinct structural states include differing proportions of crystalline phase regions and amorphous phase regions of the phase change material, where the phase-change material is reversibly transformable between the different states. In the crystalline state, the phase change material has lower resistivity; while in the amorphous state, it has higher resistivity. Continuous variations in resistivity over a wide range can be achieved through control of the relative proportions of crystalline phase regions and amorphous phase regions in a volume of phase-change material. The range of resistance values is generally bounded by a set state and a reset state of the chalcogenide material. The set state is a low resistance structural state whose electrical properties are primarily controlled by the crystalline portion of the chalcogenide material and the reset state is a high resistance structural state whose electrical properties are primarily controlled by the amorphous portion of the chalcogenide material.

Each memory state of a chalcogenide memory material corresponds to a distinct resistance value and each memory resistance value signifies a unique data value. Operationally, the chalcogenide material can be programmed into a particular memory state by providing an electric current pulse of appropriate amplitude and duration to transform the chalcogenide material into the structural state having the desired resistance value. By controlling the amount of energy provided to a chalcogenide material, it is possible to control the relative proportions of crystalline and amorphous phase regions within a volume of the material and thus control the structural (and memory) state of the chalcogenide material. Each memory state can be identified or read by measuring the resistance. The energy of the read signal is sufficiently low to prevent disturbance of the structural state of the phase-change material so that the read operation is non-destructive.

Programming among the different states is fully reversible and the memory devices can be written over a very large number of programming cycles and read over a large number of cycles to provide robust and reliable operation. Once programmed, the resistive memory states of chalcogenide memory materials are stable and persist until subjected to another programming operation. As a result, chalcogenide memory materials offer the benefit of non-volatile operation. The variable resistance memory functionality of chalcogenide materials is currently being exploited in the OUM (Ovonic Universal (or Unified) Memory) devices that are beginning to appear on the market. Basic principles and operation of OUM type devices are presented, for example, in U.S. Pat. Nos. 6,859,390; 6,774,387; 6,687,153; and 6,314,014; the disclosures of which are incorporated by reference herein.

Current commercial development of the chalcogenide materials is also oriented toward the fabrication of device arrays. Chalcogenide materials offer the promise of high density arrays that can operate according to traditional binary data storage or according to a multiple bit data storage scheme. Chalcogenide arrays further offer the prospect of integrating memory, logic, and data processing capabilities on a single chip, thereby enabling high speed, low cost, and highly functional operation.

In order to expand the commercial opportunities for chalcogenide memories and switches, it is desirable to identify new chalcogenide compositions, device structures, and methods of programming that lead to improved performance. Outstanding concerns that have been identified in the prior art include a need to condition as-fabricated devices, variability of performance during the operational life of the device, and premature failure during cycling. The need to condition is believed to originate from the presence of impurities or resistive phases at the interface of the active material with an electrode. In the conditioning process, electrical pulses are applied to perfect the interface by breaking down resistive phases and homogenizing the local composition. Performance inconsistencies arise when programming conditions vary over time or upon repeated use of the device. Programming conditions that may vary include programming energy and resistance. Premature failure occurs when it is no longer possible to reversibly operate a device between its programming states. In memory devices, failure occurs when it is not possible to reversibly transform the device between its different resistance states and in switching devices, failure occurs when it is not possible to reversibly transform the device from its conductive and resistive states.

Each of the concerns noted above is related at least in part to the quality of the interface between the active memory or switching material and one or more electrodes. A poor quality interface may lead to voids that promote the formation of oxides or other resistive phases. Voids may also prevent adequate adhesion of the active material to the electrode and diminish the quality of electrical contact between the active material and the electrode. Poor electrical contact leads to increases in programming energy and variability in programming energy due to localization of current in areas of the electrode that provide good electrical contact. Instead of spreading uniformly across the electrode surface, the programming current localizes in the regions of good electrical contact. Localization has the effect of significantly increasing current density over the area of good electrical contact. The high current density leads to the development of high local temperatures through Joule heating that may damage the electrode surface or cause the active material to volatilize. Loss of active material through volatilization creates gaps and enlarges voids at the interface. These effects tend to be progressive with cycling and lead to variations in resistance and other properties over the operational life of the device. Ultimately, catastrophic failure occurs.

To improve the consistency and longevity of device performance, it is desirable to fabricate devices having a high quality interface between the active material and the device electrodes.

### SUMMARY OF THE INVENTION

This invention provides an electrical device having improved electrical contact between the active material and one or more device electrodes. The surface of the device electrode has been treated to reduce roughness to provide a smooth surface for adherence of the active material. By smoothing the surface, voids and irregularities that would otherwise form at the interface between the active material and the electrode are suppressed and the quality of the interface improves.

The electrical device includes an active material in electrical communication with two electrodes, where application of a voltage or current signal between the two electrodes influences the state of the active material. At least one of the electrodes has been treated to reduce the roughness of the surface that forms an interface with the active material. The active material may be in direct contact with the reduced roughness electrode surface and may completely or partially cover the surface of the reduced roughness electrode. The device structure may have a pore geometry in which a dielectric material separates the two electrodes and the active material is disposed within an opening of the dielectric material that extends between the two electrodes. The device structure may also include a breakdown layer or barrier layer disposed between the active material and treated electrode surface.

The invention includes a method for making a device that includes forming a conductive layer, treating the conductive layer to smooth its surface, and forming an electrically active material on the treated conductive surface. The invention also includes a method for making a device that includes forming a conductive layer, treating the conductive layer to smooth its surface, forming a dielectric material on the treated conductive surface, forming an opening in the dielectric material to expose the treated conductive surface, and forming an electrically active material in the opening. Treatment of the conductive layer may include sputtering its surface. In one embodiment, the sputter treatment is a soft sputter etch. Other methods of reducing the roughness of the electrode surface on which the active material is formed include chemical etches, polishing, plasma treatment, and annealing. The methods may also include reducing the roughness of the surface of the active material and/or formation of a conductive layer on or over the active material.

The conductive layer may be a metal, metal alloy, or conductive compound comprising one or more metal or semiconducting elements. The active material may be a memory material or electrical switching material. Representative active materials include non-volatile memory materials, variable resistance memory materials, phase-change materials, memristor materials, chalcogenide materials, electrical switching materials, and Ovonic threshold switching materials.

### BRIEF DESCRIPTION OF THE DRAWINGS

FIG. 1A is a depiction of the I-V characteristics of a chalcogenide material in an initial reset state.

FIG. 1B is a depiction of the I-V characteristics of a chalcogenide material in an initial set state.

FIG. 2 is an illustrative Resistance vs. Energy/Current plot for a chalcogenide phase-change material.

FIG. 3 depicts a device structure including an electrically-active material disposed between a lower electrode and an upper electrode.

FIG. 4 depicts a device structure including an electrically-active material disposed within an opening of a surrounding dielectric layer and between a lower electrode and an upper electrode.

FIG. 5A is a schematic depiction of a rough electrode surface.

FIG. 5B is a schematic depiction of an active material formed over a rough electrode surface.

FIG. 6A is a schematic depiction of a rough electrode surface.

FIG. 6B is a schematic depiction of a smoothed electrode surface.

FIG. 6C is a schematic depiction of an active material formed over a smoothed electrode surface.

FIG. 7A is an image of an untreated, as-deposited surface of a carbon electrode layer.

FIG. 7B an image of the surface of a carbon electrode layer after a soft sputter etch treatment.

FIG. 8A is an image of an untreated, as-deposited surface of a TiAlN electrode layer.

FIG. 8B is an image of the surface of a TiAlN electrode layer after a soft sputter etch treatment.

FIG. 9A is a cross-sectional image of a pore device at an intermediate stage of fabrication with an as-deposited, untreated electrode surface.

FIG. 9B is a top view image of the as-deposited, untreated electrode surface of the device shown in FIG. 9A.

FIG. 10A is a cross-sectional image of a pore device at an intermediate stage of fabrication with an electrode surface that has been treated with a sputter etch process.

FIG. 10B is a top view image of the treated electrode surface of the device shown in FIG. 10A.

FIG. 11 is a cross-sectional image of a fully fabricated pore device.

FIG. 12A presents the I-V characteristics of a variant of the device shown FIG. 11 in which the active material was formed directly on an electrode in its as-fabricated state.

FIG. 12B presents the I-V characteristics of a variant of the device shown FIG. 11 in which the active material was formed directly on an electrode that was subjected to a sputter etch treatment.

FIG. 13A presents the R-I characteristics of a variant of the device shown FIG. 11 in which the active material was formed directly on an electrode in its as-fabricated state.

FIG. 13B presents the R-I characteristics of a variant of the device shown FIG. 11 in which the active material was formed directly on an electrode that was subjected to a sputter etch treatment.

### DETAILED DESCRIPTION OF THE ILLUSTRATED EMBODIMENTS

Although this invention will be described in terms of certain preferred embodiments, other embodiments that are apparent to those of ordinary skill in the art, including embodiments that do not provide all of the benefits and features set forth herein, are also within the scope of this invention. Accordingly, the scope of the invention is defined only by reference to the appended claims.

This invention provides an electrical device having an electrically-active material in electrical communication with two or more electrodes, where at least one of the electrodes has a surface that has been treated to reduce roughness. In one embodiment, the active material is in direct contact with the treated electrode surface. The treated electrode has a smooth surface that improves the quality of the interface between the active material and the electrode. The improved interface promotes good adhesion and good electrical contact.

In order to appreciate the benefits of the instant invention, it is helpful to review the basic operational characteristics of representative active materials. The following discussion focuses on chalcogenide phase-change materials and Ovonic threshold switching materials as illustrative electrical memory and switching materials. The behavior (including switching, memory, and accumulation) and chemical compositions of chalcogenide materials have been described, for example, in the following U.S. Pat. Nos. 6,671,710; 6,714,954; 6,087,674; 5,825,046; 5,687,112; 5,912,839; 5,596,522; 5,536,947; 5,534,711; 5,296,716; 5,166,758; and 3,530,441, the disclosures of which are hereby incorporated by reference. The basic principles of the instant invention, however, apply equally to other forms of phase-change, state-change or variable resistance materials, such as pnictides, memristor materials, resistive random access memory (RRAM or ReRAM) materials, programmable metallization materials, polymer memory materials, metal nanoparticle memory materials, other classes of materials transformable between two or more states distinguishable on the basis of structure, physical property or chemical property, and other classes of electrical switching materials.

An important feature of the chalcogenide-based phase-change memory materials is their ability to undergo a phase transformation between or among two or more structural states. The phase-change materials have structural states that may include a crystalline state, one or more partially-crystalline states and an amorphous state. The crystalline state may be a single crystalline state or a polycrystalline state. A partially-crystalline state refers to a structural state in which a volume of chalcogenide or phase-change material includes an amorphous portion and a crystalline portion. A partially-crystalline state may also be referred to herein as a mixed crystalline-amorphous state. Generally, a plurality of partially-crystalline states exists for the chalcogenide or phase-change material that may be distinguished on the basis of the relative proportion of the amorphous and crystalline portions. Fractional crystallinity is one way to characterize the structural states of a chalcogenide phase-change material. The fractional crystallinity of the crystalline state is 100%, the fractional crystallinity of the amorphous state is 0%, and the fractional crystallinities of the partially-crystalline states may vary continuously between 0% (the amorphous limit) and 100% (the crystalline limit). Phase-change chalcogenide materials are thus able to transform among a plurality of structural states that vary inclusively between fractional crystallinities of 0% and 100%.

Transformations among the structural states are induced by providing energy to the phase-change material. Energy in various forms can induce structural transformations of the crystalline and amorphous portions and thus can influence the fractional crystallinity of the material. Suitable forms of energy include one or more of electrical energy, thermal energy, optical energy or other forms of energy (e.g. particle-beam energy) that induce electrical, thermal or optical effects in a chalcogenide material. Continuous and reversible variability of the fractional crystallinity is achievable by controlling the energy environment of the phase-change material. A crystalline state can be transformed to a partially-crystalline or an amorphous state, a partially-crystalline state can be transformed to a crystalline, amorphous or different partially-crystalline state, and an amorphous state can be transformed to a partially-crystalline or crystalline state through proper control of the energy environment of a chalcogenide phase-change material. Some considerations associated with the use of thermal, electrical and optical energy to induce structural transformations are presented in the following discussion.

The use of thermal energy to induce structural transformations exploits the thermodynamics and kinetics associated with the crystalline to amorphous or amorphous to crystalline phase transitions. An amorphous phase may be formed, for example, from a partially-crystalline or crystalline state by heating a chalcogenide phase-change material above its melting temperature and cooling at a rate sufficient to inhibit the formation of crystalline phases. A crystalline or higher fractional crystallinity phase may be formed from an amorphous or partially-crystalline state, for example, by heating a chalcogenide phase-change material above the crystallization temperature for a sufficient period of time to effect nucleation and/or growth of crystalline domains. The crystallization temperature is below the melting temperature and corresponds to the minimum temperature at which crystallization may occur. The driving force for crystallization is typically thermodynamic in that the free energy of a crystalline or partially-crystalline state in many chalcogenide phase-change materials is lower than the free energy of an amorphous state so that the overall energy of a chalcogenide phase-change material decreases as the fractional crystallinity increases. Formation (nucleation and growth) of a crystalline state or crystalline domains within a partially-crystalline or amorphous state is kinetically enabled up to the melting temperature, so that heating promotes crystallization by providing energy that facilitates the rearrangements of atoms needed to form crystalline phases or domains.

The fractional crystallinity of a partially-crystalline state can be controlled by controlling the temperature or time of heating of the partially-crystalline state or by controlling the temperature or rate of cooling of an amorphous or partially-crystalline state. Through proper control of the peak temperature, time of heating and rate of cooling, structural states over the full range of fractional crystallinity can be achieved for the chalcogenide phase-change materials.

The use of electrical energy to induce structural transformations relies on the application of electrical (current or voltage) pulses to a chalcogenide phase-change material. The mechanism of electrically-induced structural transformations includes Joule heating, which is created by resistance to current flow. Joule heating corresponds to a conversion of electrical energy to thermal energy and leads to an increase in the temperature of the chalcogenide phase-change material. By controlling the current density, the temperature can be controlled.

The crystalline phase portions of a chalcogenide phase-change material are sufficiently conductive to permit current densities that provide efficient Joule heating. The amorphous phase portions, however, are much less conductive and ordinarily would not support current densities sufficient to heat the material to the crystallization temperature. As described more fully hereinbelow, however, the amorphous phase of many chalcogenide phase-change materials can be electrically switched to a highly conductive intermediate (dynamic) state upon application of a voltage greater than the threshold voltage. In the dynamic state, the material can support a current density that is high enough to heat the material to the crystallization temperature through Joule heating. By controlling the magnitude and/or duration of electrical pulses applied to a chalcogenide phase-change material, it is possible to continuously vary the fractional crystallinity through controlled interconversion of the crystalline and amorphous phases.

The influence of electrical energy on a chalcogenide phase-change material is generally depicted in terms of the I-V (current-voltage) and R-I (resistance-current) relationships of the material. The I-V relationship shows the current response of the material as a function of applied voltage and the R-I relationship shows the variation of the electrical resistance of the material as a result of applying electrical energy or as a function of the magnitude of the current or voltage pulse applied to the material. The resistance plotted on the R-I plot is the resistance measured at a fixed time (t0) after the application of the current pulse (I) and is measured at a sufficiently low voltage as to not disturb the memory state. A brief discussion of the I-V and R-I characteristics of chalcogenide phase-change materials follows.

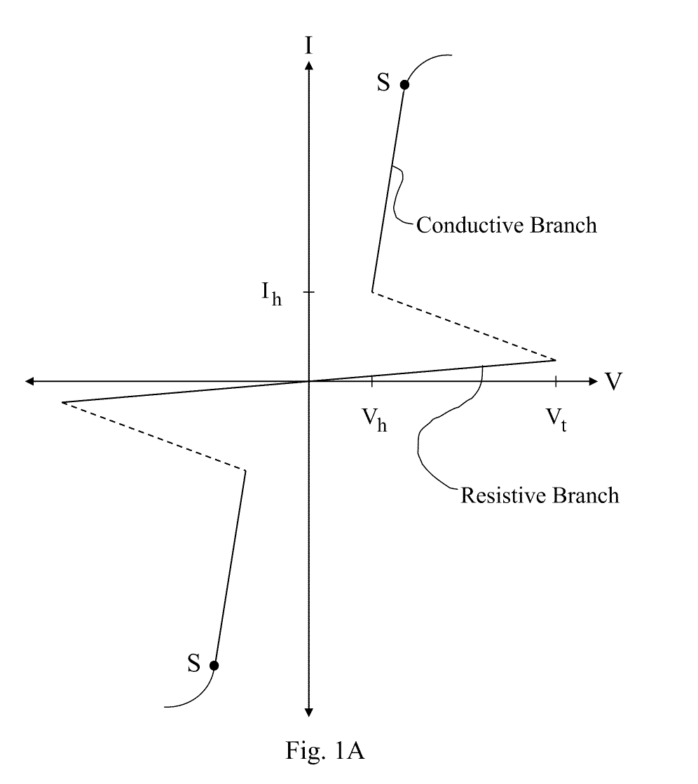

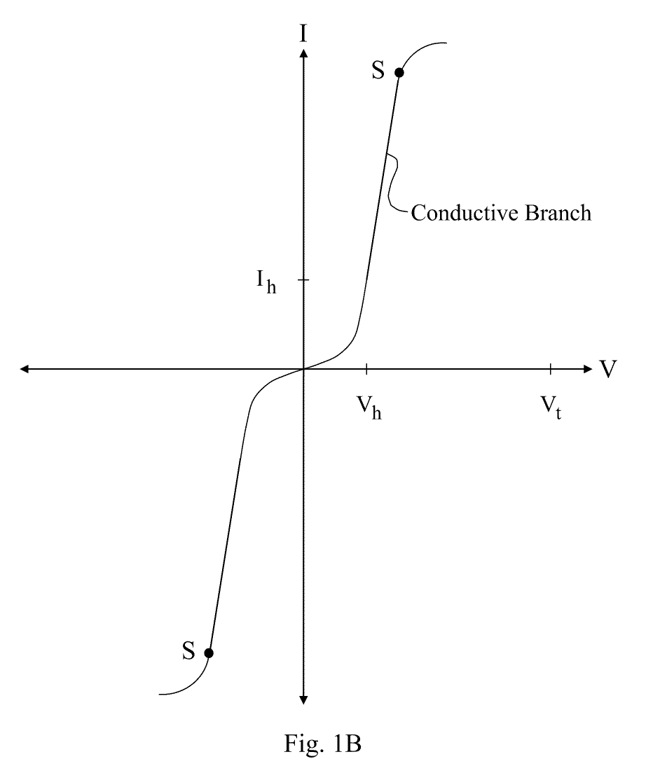

The I-V response of many chalcogenide phase-change materials exhibits an electrical switching event in which the material undergoes a transformation from a more resistive state to a more conductive state. When present, an electrical switching event is generally observed only in amorphous phase chalcogenide materials or mixed crystalline-amorphous phase chalcogenide materials and is ordinarily not observed in purely crystalline phase chalcogenide materials. As discussed more fully hereinbelow, the limiting predominantly crystalline and amorphous phase structural states of a chalcogenide phase-change material are normally referred to as the “set” and “reset” states, respectively. FIG. 1A and the following discussion of electrical switching is an illustrative example that presupposes that the chalcogenide phase-change material is initially in the reset state.

A schematic depiction of the electrical switching event of a representative chalcogenide phase-change material in the reset state is presented in FIG. 1A. The depiction of FIG. 1A corresponds to a two-terminal device configuration in which two spacedly disposed electrodes are in contact with a chalcogenide material and the current I corresponds to the current passing between the two electrodes. The I-V curve of FIG. 1A shows the current passing through the material as a function of the voltage applied across the material by the electrodes. The I-V characteristics of the material are often symmetric with respect to the polarity of the applied voltage as shown in FIG. 1A. For convenience, we consider the first quadrant of the I-V plot of FIG. 1A (the portion in which current and voltage are both positive) in the discussion of chalcogenide switching behavior that follows. An analogous description that accounts for polarity applies to the third quadrant of the I-V plot.

The I-V curve includes a resistive branch and a conductive branch. The branches are labeled in FIG. 1A. The resistive branch corresponds to the regime in which the current passing through the material is a weak function of, and generally proportional to, the applied voltage across the material. This branch generally exhibits a smaller slope in the I-V plot than the conductive branch and often appears as a nearly horizontal line in the first and third quadrants of FIG. 1A. The conductive branch, also referred to as the “dynamic” or “dynamic on” state of the material or device, corresponds to the regime in which the current passing through the material is less impeded and flows more easily under the voltage applied across the material. This branch exhibits a large slope in the I-V plot and often appears as a nearly vertical line in the first and third quadrants of FIG. 1A.

The slopes of the resistive and conductive branches shown in FIG. 1A are illustrative and not intended to be limiting, the actual slopes may depend on the chemical composition or physical state of the chalcogenide phase-change material, device geometry, circuit configuration, series resistances, and electrical contacts. The slope of the resistive branch, for example, may be greater or lesser than the slope indicated in FIG. 1A and may vary depending on the relative proportions of crystalline and amorphous phase content present in the material. The difference between the threshold voltage and holding voltage may also be greater or lesser than indicated in FIG. 1A. Although the threshold voltage is normally greater than the holding voltage, in some devices the threshold voltage and holding voltage may be similar in magnitude. In some devices, the threshold current and holding current may also be similar in magnitude. Since the conductivity of the chalcogenide material in the conductive branch is typically higher than the conductivity of the surrounding contacts or circuitry, the slope of the conductive branch is often controlled by resistances in series with the chalcogenide material. When device conditions are such that the material is described by a point on the resistive branch of the I-V curve, the material or device may be said to be in a “resistive” state. When device conditions are such that the material is described by a point on the conductive branch of the I-V curve, the material or device may be said to be in a “conductive” state.

The switching properties of the chalcogenide phase-change material are shown in FIG. 1A. We begin with a device that has no voltage applied across it. When no voltage is applied across the material, the material is in a resistive state and no current flows. This condition corresponds to the origin of the I-V plot shown in FIG. 1A. The material remains in a resistive state as the applied voltage is increased, up to a threshold voltage (labeled Vₜ in the first quadrant of FIG. 1A). The slope of the I-V curve for applied voltages between 0 and Vₜ is small in magnitude and indicates that the material has a relatively high electrical resistance. The high resistance implies low electrical conductivity and as a result, the current flowing through the material increases only weakly as the applied voltage is increased. Since the current through the material is very low, the resistive state of the chalcogenide may be referred to as the OFF state of the material (or device). The conductive state of the material may be referred to as the ON state of the material (or device) since the current through a device in the conductive state is high and increases significantly with increasing applied voltage.

When the applied voltage equals or exceeds the threshold voltage, the material transforms (switches) from the resistive branch to the conductive branch of the I-V curve. The switching event occurs essentially instantaneously and is depicted by the dashed line in FIG. 1A. Upon switching, the device voltage decreases significantly and the device current becomes much more sensitive to changes in the device voltage. The material remains in the conductive branch as long as a minimum current, labeled Iₕ in FIG. 1A, is maintained. We refer to Iₕ as the holding current and the associated voltage Vₕ as the holding voltage of the device. If the device conditions after switching are changed so that the current becomes less than Iₕ, the material normally returns to the resistive branch of the I-V plot and requires subsequent application of a threshold voltage to resume operation on the conductive branch. If the current is only momentarily (a time less than the recovery time of the material) reduced below Iₕ, the conductive state of the material may be recovered upon restoring the current to or above Iₕ. The recovery time of chalcogenide materials has been discussed in the article “Amorphous Semiconductors for Switching, Memory, and Imaging Applications”, IEEE Transactions on Electron Devices, vol. ED-20, p. 91-105 (1973) by S. R. Ovshinsky and H. Fritzsche; the disclosure of which is incorporated by reference herein.

The switching effect of the instant devices originates from a transformation of the chalcogenide material from a resistive state to a conductive state upon application of a threshold voltage, Vₜₕ. According to one model of the switching transformation, application of the threshold voltage causes the formation of a conductive channel or filament within the material. At the threshold voltage, the electric field experienced by the material is sufficiently high to induce a breakdown or avalanche effect whereby electrons (believed to be lone pair electrons) are removed from atoms to form a highly conductive, plasma-like filament of charge carriers. Rather than being bound to atoms, some electrons become unbound and highly mobile. As a result, a conductive channel or filament forms. The conductive filament constitutes a conductive volume within the otherwise resistive chalcogenide material. The conductive filament extends through the chalcogenide material between the device terminals and provides a low resistance pathway for electrical current. Portions of the chalcogenide material outside of the filament remain resistive. Since electric current traverses the path of least resistance, the presence of a conductive filament renders the chalcogenide material conductive and establishes a conductive state. The creation of a conductive filament is the event that underlies the switching of the chalcogenide material from a resistive state to a conductive state.

The conductive filament is maintained between the device terminals as long as the device current remains at or above the holding current. A conductive filament is present for all points along the conductive branch, but the cross sectional area of the filament differs for different points along the conductive branch. Depending on operating conditions within the conductive branch, the filament can be narrow or wide. As the applied voltage is increased along the conductive branch, the cross section of the filament is enlarged as the applied voltage is increased. The enlarged filament indicates that a greater volume of the chalcogenide material exhibits high conductivity. When the filament reaches the dimensions of the pore, it can no longer expand and the device resistance increases (beginning at points S in FIG. 1A). Due to the increased fractional conversion of the material to the highly conductive dynamic state through filament expansion, the chalcogenide material can support increasingly higher current in the conductive state as the applied voltage is increased. Variations of the voltage applied to a chalcogenide material operating in the conductive branch modify the width or thickness of the filament in directions lateral to the direction of current flow. The net effect of varying the applied voltage of a chalcogenide material operating in the conductive branch is to modify the volume fractions of the conductive and resistive portions. Such modifications ultimately enable control over the resistance of the material through variations in the relative proportions of crystalline and amorphous phase regions in the structural state of the chalcogenide material.

When the chalcogenide phase-change material is initially in the set state, the switching event shown in FIG. 1A is not observed. Instead, the I-V response exhibits a monotonic increase in current with increasing voltage (FIG. 1B). The I-V response of a material in the set state merges with the conductive branch (dynamic on state) shown in FIG. 1A for a device initially in the reset state. Mixed crystalline-amorphous states generally exhibit a switching event, but at voltages below the threshold voltage observed for the reset state. A progressive decrease in the voltage at which switching occurs is observed as the crystalline phase volume fraction increases from the reset state to the set state. The I-V characteristics of mixed crystalline-amorphous states are generally intermediate between those depicted for the reset and set states in FIGS. 1A and 1B, respectively. All of the states, however, generally share a common dynamic on state.

Chalcogenide materials of many chemical compositions undergo the foregoing switching effect. Representative chalcogenide materials are those that include one or more elements from column VI of the periodic table (the chalcogen elements) and optionally one or more chemical modifiers from columns III, IV or V. One or more of S, Se, and Te are the most common chalcogen elements included in the active material of the instant devices. The chalcogen elements are characterized by divalent bonding and the presence of lone pair electrons. The divalent bonding leads to the formation of chain and ring structures upon combining chalcogen elements to form chalcogenide materials and the lone pair electrons provide a source of electrons for forming a conducting filament. Trivalent and tetravalent modifiers such as Al, Ga, In, Ge, Sn, Si, P, As and Sb enter the chain and ring structures of chalcogen elements and provide points for branching and crosslinking. The structural rigidity of chalcogenide materials depends on the extent of crosslinking and leads to a broad classification of chalcogenide materials, according to their ability to undergo crystallization or other structural rearrangements, into one of two types: threshold switching materials and phase-change (or memory) materials. The threshold switching materials may be referred to herein as Ovonic threshold switching materials.

Both types of chalcogenide materials display the switching behavior shown in FIG. 1A, but differ in their structural response to filament formation. The threshold switching materials generally possess a higher concentration of modifiers and are more highly crosslinked than the phase-change materials. They are accordingly more rigid structurally. Threshold switching materials are amorphous and show little or no tendency to crystallize because the atomic rearrangements required to nucleate and grow a crystalline phase are inhibited by the rigidity of the structure. Threshold switching materials do not undergo a crystallization transformation during switching and remain amorphous upon removing the applied voltage after switching.

Phase-change chalcogenide materials, on the contrary, are lightly crosslinked and more easily undergo full or partial crystallization. An amorphous phase-change material undergoes filament formation in the presence of a threshold voltage as described in FIG. 1A hereinabove. Once in the conductive branch, however, the phase-change material may undergo nucleation and growth of a crystalline phase due to Joule heating. The volume fraction of the crystalline phase depends on the magnitude, duration and falltime of the current passing through the phase-change material. If formed, the crystalline phase is retained upon removing the applied voltage after switching. Similarly, Joule heating may increase the temperature of a crystalline region of a phase-change material to the melting point whereupon sufficiently rapid removal of the current may quench an amorphous phase as described hereinabove. Through appropriate selection of device operating conditions, the amorphous-crystalline transformation of chalcogenide phase-change memory materials becomes reversible over many cycles.

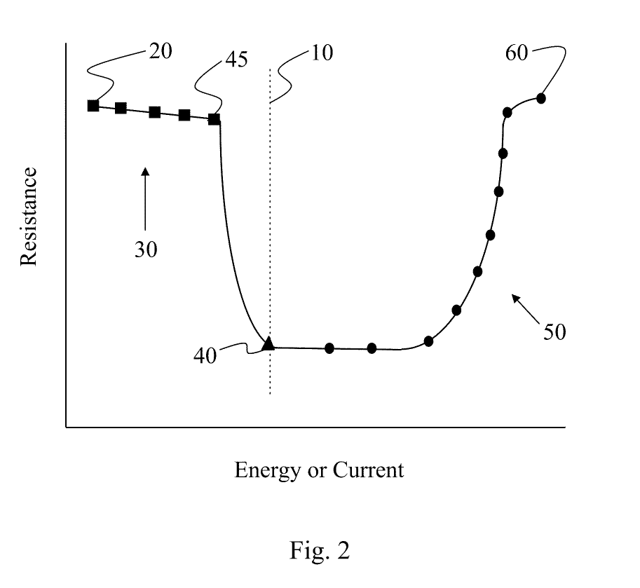

The R-I response is a meaningful depiction of the characteristics of the chalcogenide phase-change memory devices and provides a representation of the effect of structural transformations associated with the crystalline-amorphous phase-change process on electrical properties. A representative depiction of the electrical resistance (R) of a chalcogenide memory device as a function of electrical energy or current pulse magnitude (Energy/Current) is presented in FIG. 2 for a device in which the chalcogenide material begins in the reset state (discussed below). FIG. 2 may generally be referred to as a resistance plot.

The resistance plot includes two characteristic response regimes of the device to electrical energy. The regimes are approximately demarcated with the vertical dashed line 10 shown in FIG. 2. The regime to the left of the line 10 may be referred to as the accumulating regime of the chalcogenide material. The accumulation regime is distinguished by a nearly constant or gradually varying electrical resistance with increasing electrical energy until a highly conducting state is reached. In most cases there is a region where device temperatures favor crystalline growth and when a percolation path forms, a pronounced resistance drop is observed for the device. The accumulation regime extends, in the direction of increasing energy, from the leftmost point 20 of the resistance plot, through a plateau region (generally depicted by 30) corresponding to the range of points over which the resistance variation is small or gradual to the set point or state 40 that follows an abrupt decrease in electrical resistance. The plateau 30 may be horizontal or sloping.

The left side of the resistance plot is referred to as the accumulating regime because the structural state of the chalcogenide material cumulatively evolves as energy is applied. The fractional crystallinity of the structural state correlates with the total accumulation of applied energy. The leftmost point 20 corresponds to the structural state in the accumulating regime having the lowest fractional crystallinity and may be referred to as the reset state. This state may be fully amorphous or may be primarily amorphous with some degree of crystalline content. As energy is added, the chalcogenide material progresses among a plurality of partially-crystalline states with increasing fractional crystallinity along the plateau 30. Selected accumulation states (structural states in the accumulation region) are marked with squares in FIG. 2.

Upon accumulation of a sufficient amount of applied energy, the fractional crystallinity of the chalcogenide material increases sufficiently to effect a setting transformation characterized by a dramatic decrease in electrical resistance and stabilization of the set state 40. The structural states in the accumulation regime may be referred to as accumulation states of the chalcogenide material. Structural transformations in the accumulating regime are unidirectional in the sense that they progress in the direction of increasing applied energy within the plateau region 30 and are reversible only by first driving the chalcogenide material through the set point 40 and resetting (melting and quenching the device). Once the reset state is obtained, lower amplitude current pulses can be applied and the accumulation response of the chalcogenide material can be retraced. It is possible to reversibly transform between the set and reset states over multiple cycles of operation.

While not wishing to be bound by theory, it is believed that the addition of energy to a chalcogenide material in the accumulating regime leads to an increase in fractional crystallinity through the nucleation of new crystalline domains or growth of existing crystalline domains or a combination thereof. It is further believed that the electrical resistance varies only gradually along the plateau 30, despite the increase in fractional crystallinity, because the crystalline domains form or grow in relative isolation of each other so as to prevent the formation of a contiguous crystalline network that spans the chalcogenide material between the two device electrodes. This type of crystallization may be referred to as sub-percolation crystallization.

The setting transformation coincides with a percolation threshold in which a contiguous, interconnected crystalline network forms within the chalcogenide material and bridges the space between the two electrodes of the device. Such a network may form, for example, when crystalline domains increase sufficiently in size to impinge upon neighboring domains. Since the crystalline phase of chalcogenide materials is more conductive and less resistive than the amorphous phase, the percolation threshold corresponds to the formation of a contiguous low resistance conductive pathway through the chalcogenide material. As a result, the percolation threshold is marked by a dramatic decrease in the resistance of the chalcogenide material. The leftmost point 20 of the accumulation regime may be an amorphous state or a partially-crystalline state lacking a contiguous crystalline network. Sub-percolation crystallization commences with an initial amorphous or partially-crystalline state and progresses through a plurality of partially-crystalline states having increasingly higher fractional crystallinities until the percolation threshold is reached and the setting transformation occurs.

The regime to the right of the line 10 of FIG. 2 may be referred to as the direct overwrite regime. The direct overwrite regime extends from the set state 40 through a plurality of intermediate states (generally depicted by 50) to a reset point or state 60. The various points in the direct overwrite regime may be referred to as direct overwrite states of the chalcogenide material. Selected direct overwrite states are marked with circles in FIG. 2. Structural transformations in the direct overwrite regime may be induced by applying an electric current or voltage pulse to a chalcogenide material. In FIG. 2, an electric current pulse is indicated. In the direct overwrite regime, the resistance of the chalcogenide material varies with the magnitude of the applied electric pulse. The resistance of a particular direct overwrite state is characteristic of the structural state of the chalcogenide material, and the structural state of a chalcogenide material is dictated by the magnitude of the applied current pulse. The fractional crystallinity of the chalcogenide material decreases as the magnitude of the current pulse increases. The fractional crystallinity is highest for direct overwrite states at or near the set point 40 and progressively decreases as the reset state 60 is approached. The chalcogenide material transforms from a structural state possessing a contiguous crystalline network at the set state 40 to a structural state that is amorphous or substantially amorphous or partially-crystalline without a contiguous crystalline network at the reset state 60. The application of current pulses having increasing magnitude has the effect of converting portions of the crystalline network into an amorphous phase and ultimately leads to a disruption or interruption of contiguous high-conductivity crystalline pathways in the chalcogenide material. As a result, the resistance of the chalcogenide material increases as the magnitude of an applied current pulse increases in the direct overwrite region.

In contrast to the accumulating region, structural transformations that occur in the direct overwrite region are reversible and bi-directional. As indicated hereinabove, each state in the direct overwrite region may be identified by its resistance and an associated current pulse magnitude, where application of the associated current pulse magnitude induces changes in fractional crystallinity that produce the particular resistance state. Application of a subsequent current pulse may increase or decrease the fractional crystallinity of an existing resistance state of the chalcogenide material. If the subsequent current pulse has a higher magnitude than the pulse used to establish the existing state, the fractional crystallinity of the chalcogenide material decreases and the structural state is transformed from the existing state in the direction of the reset state along the direct overwrite resistance curve. Similarly, if the subsequent current pulse has a lower magnitude than the pulse used to establish the existing state, the fractional crystallinity of the chalcogenide material increases and the structural state is transformed from the existing state in the direction of the set state along the direct overwrite resistance curve.

The direct overwrite states of the chalcogenide material may be used to define memory states of a memory device. Most commonly, the memory devices are binary memory devices that utilize two of the direct overwrite states as memory states, where a distinct data value (e.g. “0” or “1”) is associated with each state. Each memory state thus corresponds to a distinct structural state of the chalcogenide material and readout or identification of the state can be accomplished by measuring the resistance of the material (or device) since each structural state is characterized by a distinct resistance value. The operation of transforming a chalcogenide material to the structural state associated with a particular memory state may be referred to herein as programming the chalcogenide material, writing to the chalcogenide material or storing information in the chalcogenide material.

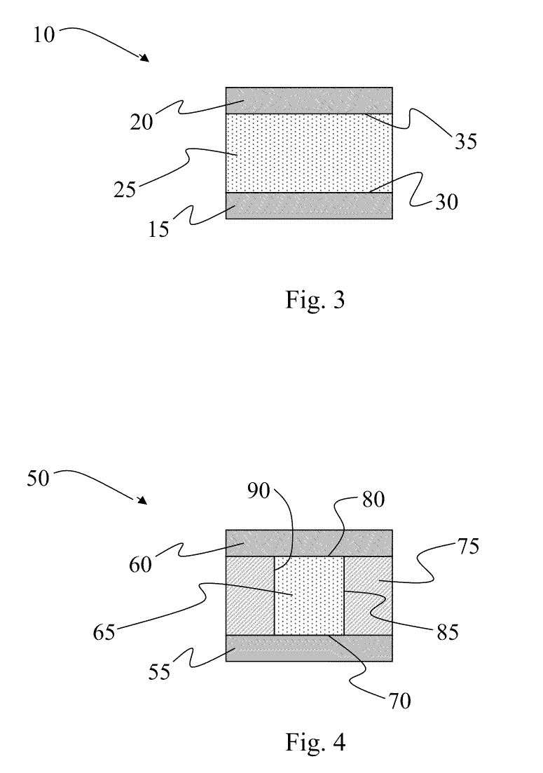

FIG. 3 depicts a typical structure of the working portion of an electrical device that includes an electrically-active material as the operational component. The electrically-active material may be referred to herein as simply the active material of the device. As indicated hereinabove, active materials in accordance with the instant invention include non-volatile memory materials, variable resistance materials, phase-change materials, resistive RAM materials, memristor materials, chalcogenide materials, electrical switching materials and threshold switching materials. Device 10 includes active material 25 disposed between lower electrode 15 and upper electrode 20. Lower electrode 15 and upper electrode 20 are conductive materials such as metals, metal alloys, metal nitrides, metal carbides, or carbon. Metal elements include transition metals and post-transition metals. Representative electrode materials include Ti, TiN, TiW, W, TiAlN, TiSiN, C, Al, Cu, and MoN.

FIG. 4 shows an alternative device structure 50 in which active material 65 is disposed between lower electrode 55 and upper electrode 60, and is further confined within an opening of dielectric material 75. The device structure shown in FIG. 4 may be referred to herein as a pore device structure. Although not shown in FIGS. 3 and 4, devices 10 and 50 are typically formed on a substrate, where the substrate may include diodes or other access devices, conductive leads, drivers, sense amplifiers, and/or other circuits that support operation of the device.

The instant invention is concerned with the interface of the active material with the surrounding electrodes. Of particular interest is the interface between the active material and the lower electrode of the device. Interest in the lower electrode interface arises because during device fabrication, the lower electrode is typically formed or deposited before the active material. As a result, the active material is deposited directly on the exposed surface of the lower electrode during fabrication and the conditions at the surface of the lower electrode influence the deposition of the active material, adhesion of the active material, and the electrical contacting characteristics.

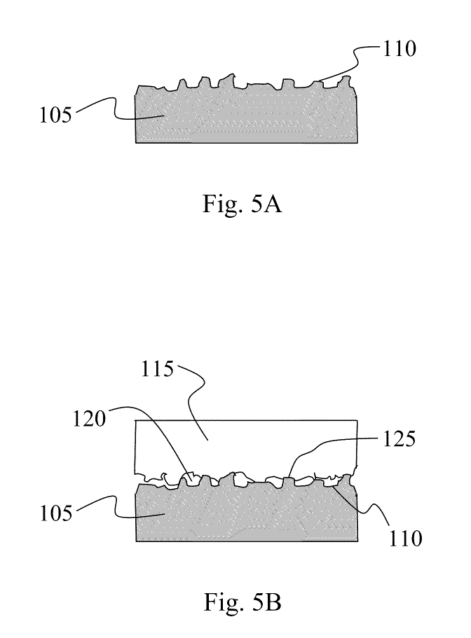

FIG. 5A shows a schematic depiction of an electrode with a rough surface. Electrode 105 includes surface 110, which is rough and bumpy. The irregular nature of surface 110 makes it difficult to achieve uniform, conformal coverage of electrode 105 during subsequent deposition of the active material in the fabrication process. Uniform coverage promotes adhesion of the active material and establishes good electrical contact between electrode 105 and the active material. Uniformity of coverage becomes increasingly difficult to achieve as the roughness of surface 110 increases and is especially problematic when the active material is deposited with a line-of-sight technique such as sputtering.

FIG. 5B schematically illustrates the uneven nature of the interface that can form between an irregular electrode surface and an active material. In FIG. 5B, active material 115 is formed directly on surface 110 of electrode 105. Because of the irregular nature of surface 110, uniformity of coverage is difficult to achieve and the interface between electrode 105 and active material 115 includes imperfections such as voids 120 that represent physical gaps between electrode 105 and active material 115. Because of the presence of voids 120, electrical contact between electrode 105 and active material 115 occurs only at selected points of contact 125. Since the current is channeled to selected contact points 125, the current density increases substantially at those points. As a result, excessive Joule heating may occur and cause damage to electrode 105 and/or active material 115.

Excessive Joule heating may also lead to an evolution of the structure and/or composition of the interface over time, which may in turn lead to variability in the performance characteristics of the active material. Many active materials are relatively low-melting materials and are susceptible to volatilization upon excessive heating. Volatilization corresponds to a vaporization of the active material (e.g. by sublimation or evaporation). The presence of voids 120 facilitates volatilization. Once volatilized, active material 115 may escape the device structure and lead to a further increase in the number or size of voids 120. Volatilization may also alter the composition of active material 115 since active material 115 is typically a multicomponent or multi-element material whose constituent components or elements differ in volatility. Excessive interfacial heating may preferentially expel the more volatile components or elements of active material 115, while leaving the less volatile components behind in the structure. As a result, the composition of active material 115 may become enriched in the less volatile components or elements over multiple cycles of operation. As the composition of active material 115 changes, so do its performance characteristics. Properties such as threshold voltage, threshold current, resistance, crystallization speed or temperature, melting point, and programming current typically vary with the composition of the active material.

The instant invention seeks to improve the quality of the electrode surface upon which an active material is deposited. By making the electrode surface smoother and more uniform, more consistent and more enduring device operation is expected. The basic objective is to reduce the roughness of the electrode surface to promote more uniform and more conformal coverage of the electrode surface with the active material. A smoothed electrode surface insures consistency of coverage across the electrode surface and improves adhesion and the integrity of contact between the active material and electrode surface. A smoothed electrode surface may also be referred to herein as a reduced roughness electrode surface.

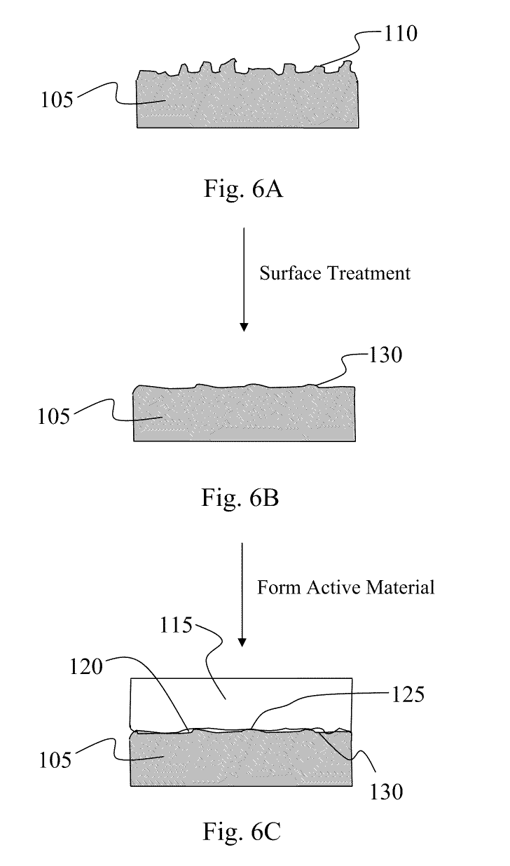

FIGS. 6A-6C show a schematic of the improvement in interfacial quality provided by the instant invention. FIG. 6A repeats the rough surface depicted in FIG. 5A. FIG. 6B shows the surface of electrode 105 after a treatment designed to reduce roughness. Treated surface 130 of electrode 105 is smoother and more uniform than surface 110 shown in FIG. 5A. Active material 115 is subsequently formed on treated surface 130 of electrode 105 to form the structure shown in FIG. 6C. Because of the reduced roughness of treated surface 130, the interface between electrode 105 and active material 115 is more regular and the consistency of coverage of active material 115 on electrode 105 is improved. To the extent that they remain, voids 120 are fewer in number and generally smaller in size relative to an untreated electrode surface. Contact points 125 tend to be flatter and less localized relative to an untreated electrode surface. Overall, surface treatment provides a more uniform interface between active material 115 and electrode 105.

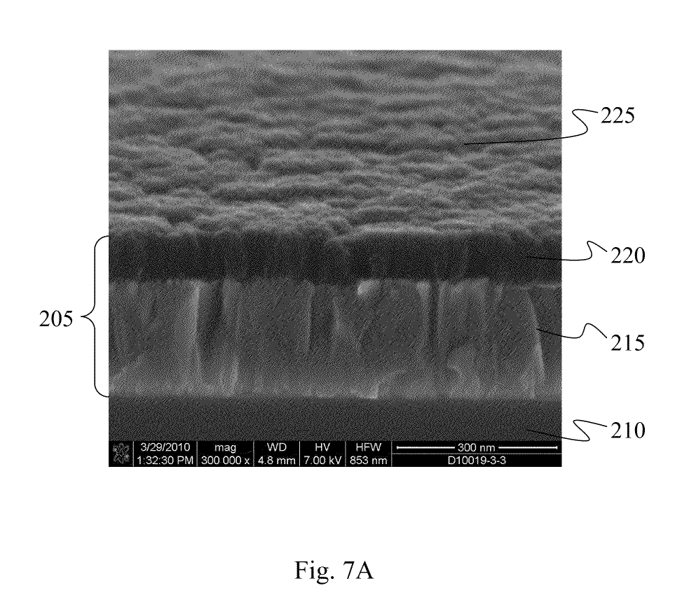

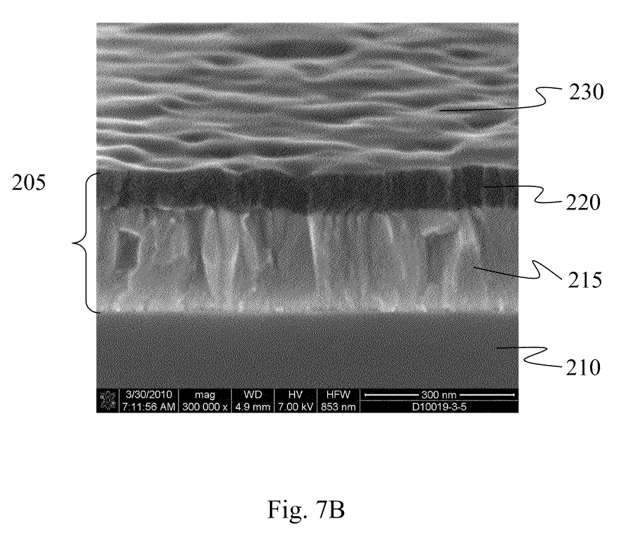

FIG. 7A shows an image of a representative electrode material prepared from a physical vapor deposition process. Electrode material 205 is a composite, dual-layer electrode situated on substrate 210. Composite electrode material 205 includes TiW layer 215 and C layer 220. The image further shows surface 225 of carbon layer 220. Surface 225 is generally rough, bumpy, and uneven. FIG. 7B shows the effect of treating surface 225 with a soft sputter etch process. In the soft sputter etch process, surface 225 is exposed to a low energy plasma. The plasma includes energized ions that bombard surface 225. Energetic collisions at the surface preferentially remove protruding features that contribute to surface roughness and lead to an overall smoothing of the electrode surface. Treated surface 230 shown in FIG. 7B is smoother and more regular than untreated surface 225 shown in FIG. 7A.

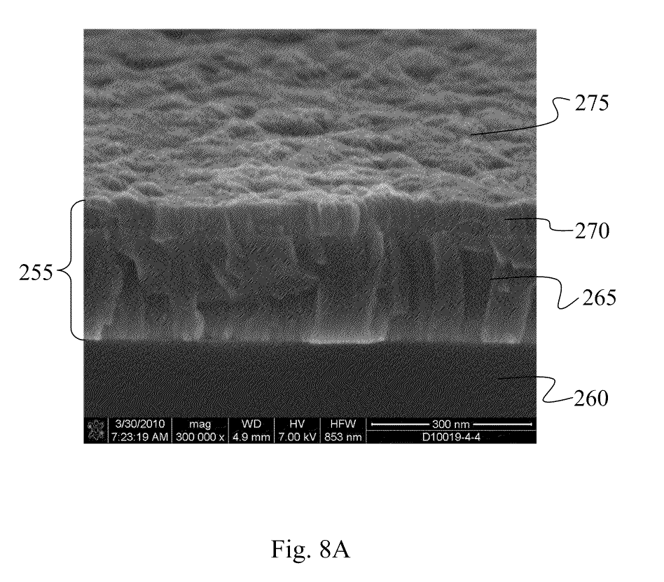

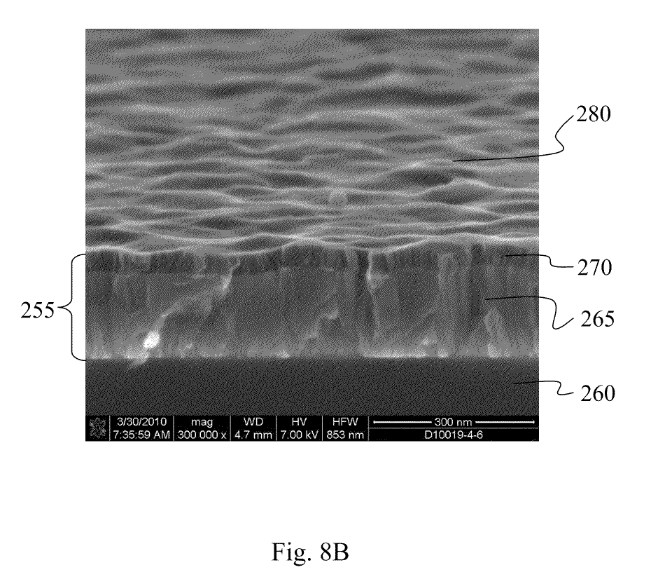

FIG. 8A shows an image of another representative electrode material prepared from a physical vapor deposition process. Electrode material 255 is a composite, dual-layer electrode situated on substrate 260. Composite electrode material 255 includes TiW layer 265 and TiAlN layer 270. The image further shows surface 275 of TiAlN layer 270. Surface 275 is generally rough, bumpy, and uneven. FIG. 8B shows the effect of treating surface 275 with a soft sputter etch process. Treated surface 280 shown in FIG. 8B is smoother and more regular than untreated surface 275 shown in FIG. 8A.

Treatment processes for reducing the roughness of an electrode surface in accordance with the instant invention include physical and chemical treatment methods. Representative treatment processes include chemical etches (e.g. HF clean), physical vapor deposition, sputtering, polishing (e.g. chemical-mechanical processing), annealing, and plasma treatment (e.g. rapid plasma clean).

In one embodiment, the treatment process is a soft sputter etch process. As is known in the art, a sputter etch process entails use of sputtering conditions to etch or ablate the surface of a material. The purpose of a sputter etch is often to remove unwanted material from a surface or to refine the dimensions of a material. A soft sputter etch is an etch process conducted under mild sputtering conditions to prevent excessive ablation of the surface. In the instant invention, the objective is to reduce the surface roughness of a conductive or electrode material and sputtering conditions are established to enable etching or removal of protrusions or other surface irregularities while avoiding excessive thinning of the conductive or electrode material. By controlling the power density and/or time of exposure of the surface to the active plasma in a sputtering process, the instant invention achieves smoothing of the surface of a conductive or electrode material without compromising its functionality.

In a typical sputtering process, the power is ˜150 W over an area of ˜1 ft² and the process is performed over a few minutes. These conditions provide a power density of ˜0.15 W/cm². In one embodiment, the power density is less than 0.25 W/cm². In another embodiment, the power density is less than 0.20 W/cm². In a further embodiment, the power density is less than 0.15 W/cm². In one embodiment, the sputter etch time is less than 15 minutes. In another embodiment, the sputter etch time is less than 10 minutes. In a further embodiment, the sputter etch time is less than 5 minutes.

The instant treatment process may be implemented in the fabrication of any active material device structure. The method extends to thin film device structures (such as shown in FIG. 3) as well as to pore or confined cell device structures (such as shown in FIG. 4). In general, the treatment process includes forming a conductive material, treating the surface of the conductive material using a process that reduces surface roughness, and forming an active material directly on the treated surface. The method may further include treatment of the active material surface and/or formation of a second conductive material on the active material surface.

The conductive layer is typically an electrode, but may also be a conductive barrier layer disposed between a device electrode and the active material to prevent electromigration or other processes that cause elements to transfer from the electrode to the active material or from the active material to the electrode.

In one embodiment, the invention provides a method for fabricating a pore or confined cell active material device structure. The method includes providing a substrate, forming a conductive material on the substrate, reducing the roughness of the surface of the conductive material, forming a dielectric material on the reduced-roughness electrode surface, forming an opening in the dielectric material to expose the reduced-roughness electrode surface, and forming an active material within the opening that directly contacts the exposed reduced-roughness electrode surface. The active material may be in direct contact with the entirety of the exposed reduced-roughness electrode surface or only a portion thereof. The dielectric material may be an oxide or nitride material. Representative dielectric materials include SiO₂, SiOₓ, Si₃N₄, and SiNₓ.

In forming a pore or confined cell device, it is preferable to treat the surface of the conductive material to reduce roughness before depositing or otherwise forming the dielectric material. In principle, the surface of the electrode could be treated after forming the opening in the dielectric material. This alternative, however, is less preferred because completion of the process of treating the lower electrode in the presence of the dielectric material may affect the integrity of the opening (e.g. alter its size, shape, or depth) and may also remove portions of the dielectric material and cause them to accumulate on the exposed electrode surface. The presence of residual dielectric material at the interface between the exposed electrode surface and the active material is undesirable since it interferes with electrical contacting and represents a highly resistant interfacial phase. By first reducing the roughness of the electrode surface and then forming a dielectric with an opening, contamination of the electrode surface with residual dielectric material is avoided.

In a further embodiment, the method of the instant invention includes forming a conductive material over the active material. As noted hereinabove, active material device structures include two or more electrodes, where application of a voltage, current or other electrical signal between at least a pair of electrodes enables programming of the active material. In one embodiment, the conductive material is formed directly on the active material. In another embodiment, the conductive material is formed on the as-fabricated surface of the active material. In a further embodiment, the as-fabricated surface of the active material is treated to reduce its roughness before the conductive material is deposited thereon. Reduction of the roughness of the surface of the active material is expected to provide benefits consistent with those described hereinabove in connection with reducing the roughness of the conductive material on which the active material is formed.

### Example 1

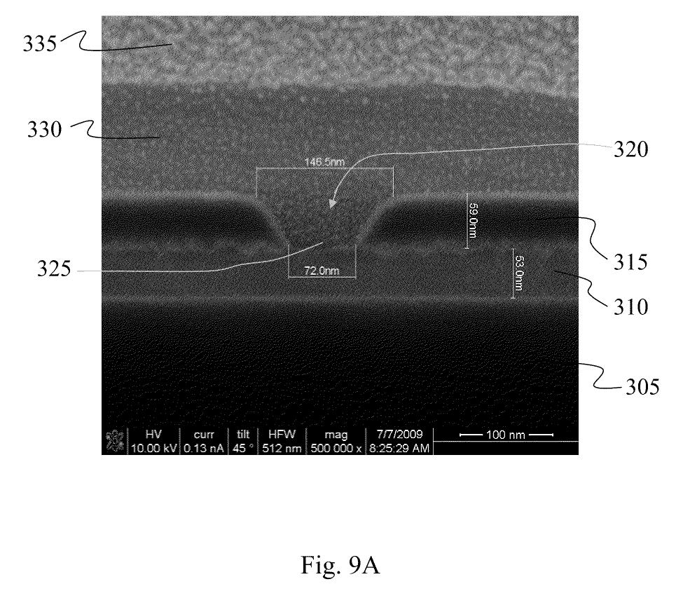

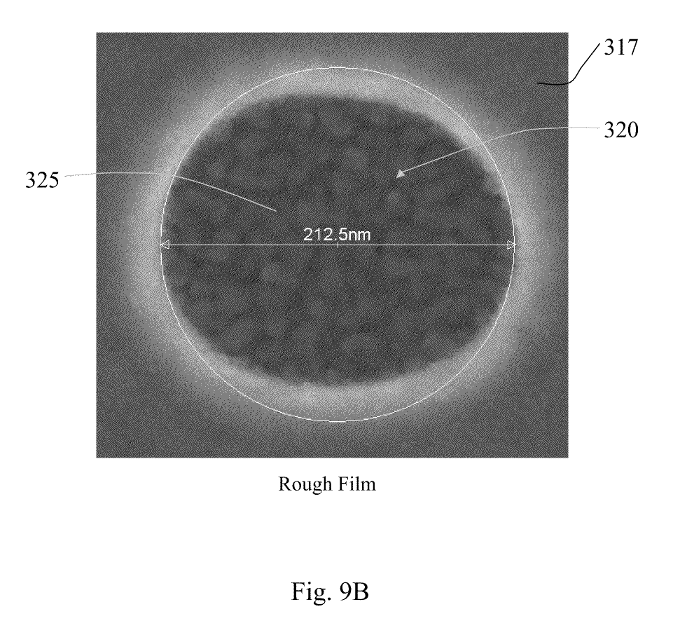

In this example, the effect of surface treatment on the morphology and surface roughness of an electrode material in a partially fabricated pore device structure is described. FIG. 9A shows a cross-sectional (FIB) image of a pore device at an intermediate stage of fabrication. The device included substrate 305, conductive layer 310 of TiAlN, and dielectric material 315. Conductive layer 310 was formed by sputtering and was not treated before deposition of dielectric material 315 (SiO₂). Dielectric material 315 included opening 320, formed by lithography, which exposed portion 325 of the surface of untreated conductive layer 310. Opening 320 had sloped sidewalls and a diameter that varied with depth. The diameter of opening 320 was approximately 72 nm at exposed surface 325 and 146 nm closer to the top surface of dielectric material 315. The structure did not include an active material. Fine-grained Pt layer 330 and large-grained Pt layer 335 were provided as capping layers to protect the surface and facilitate acquisition of the image.

Several devices at the intermediate stage of fabrication shown in FIG. 9A were prepared that included openings of various diameters. FIG. 9B shows a top view image of a device having a large diameter opening (˜212 nm) that shows the condition of exposed surface 325. A device with a large diameter was selected for the top view image to facilitate visualization of surface features. FIG. 9B shows top surface 317 of dielectric material 315 along with opening 320 and exposed surface 325. As noted hereinabove, the surface of conductive layer 310 was not treated and was present in its as-fabricated state. FIG. 9B shows that untreated exposed surface 325 had a rough, coarse, and textured morphology.

For comparison purposes, a series of devices analogous to the structure shown in FIG. 9A were prepared that included treatment of the surface of the conductive layer before deposition of the dielectric material and before forming an opening in the dielectric material. In these devices, a conductive layer was formed and subjected to a soft sputter etch treatment designed to reduce the roughness of the surface. In a typical soft sputter etch, sputtering occurred by activating a plasma in Ar gas having a pressure of ˜3 mTorr. The sputtering power density was ˜0.15 W/cm² and the sputter etch persisted for a few to several minutes. After completion of the soft sputter etch, a dielectric material was formed, an opening was formed in the dielectric material to expose a portion of the top (treated) surface of the conductive layer, and the structure was capped with Pt as described hereinabove.

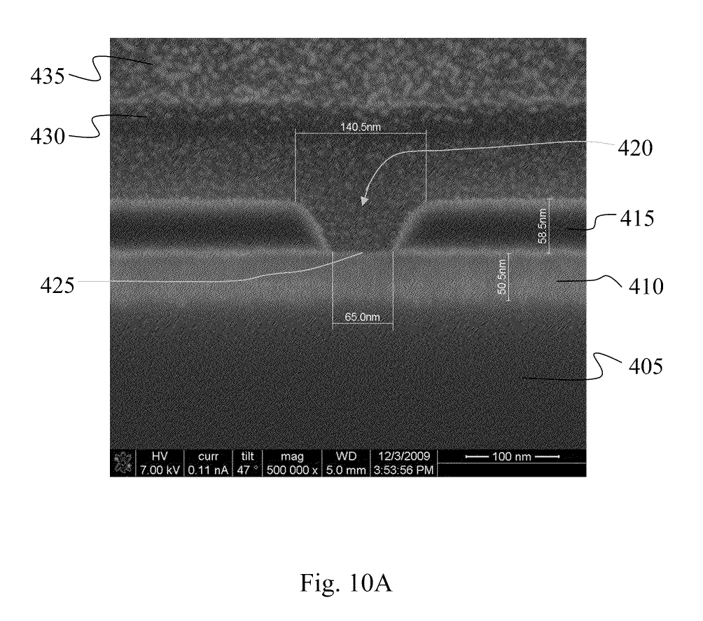

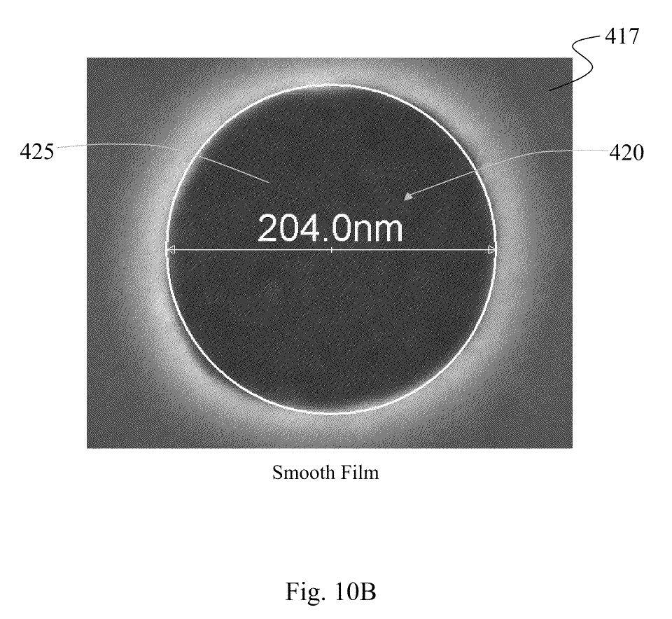

FIG. 10A shows a cross-sectional (FIB) image of a pore device with a treated conductive layer at an intermediate stage of fabrication. The device included substrate 405, conductive layer 410 of TiAlN, and dielectric material 415 (SiO₂). Conductive layer 410 was formed by sputtering and subjected to a sputter etch treatment to reduce the roughness of its surface before deposition of dielectric material 415. Dielectric material 415 was next deposited and included opening 420, formed by lithography, which exposed portion 425 of the surface of treated conductive layer 410. Opening 420 had sloped sidewalls and a diameter that varied with depth. The diameter of opening 420 was approximately 65 nm at exposed surface 425 and 140 nm closer to the top surface of dielectric material 415. The structure did not include an active material. Fine-grained Pt layer 430 and large-grained Pt layer 435 were provided as capping layers to protect the surface and facilitate acquisition of the image.

Several devices at the intermediate stage of fabrication shown in FIG. 10A were prepared that included openings of various diameters. FIG. 10B shows a top view image of a device having a large diameter opening (˜204 nm) that shows the condition of exposed surface 425. FIG. 10B shows top surface 417 of dielectric material 415 along with opening 420 and exposed surface 425. As noted hereinabove, the surface of conductive layer 410 was treated before forming dielectric material 415 and opening 420. FIG. 10B shows that treated exposed surface 425 had a smooth, low roughness morphology with little texture. FIG. 10B also shows that no debris from forming opening 420 in dielectric material 415 occurred on treated exposed surface 425.

The results of this example show that treatment of the surface of the conductive layer before forming a dielectric material in a pore-type device structure provides a smooth exposed electrode surface. In fabrication of a complete device, an active material would be formed over and within the opening of the dielectric material and would be in contact with the exposed surface of the conductive (electrode) material. This example indicates that treatment of the conductive layer provides a smooth, reduced-roughness surface for receipt of the active material.

### Example 2

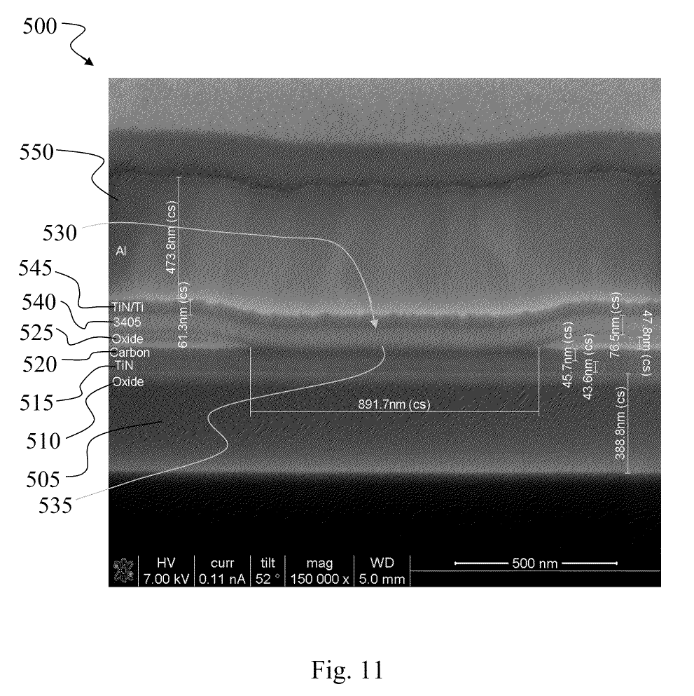

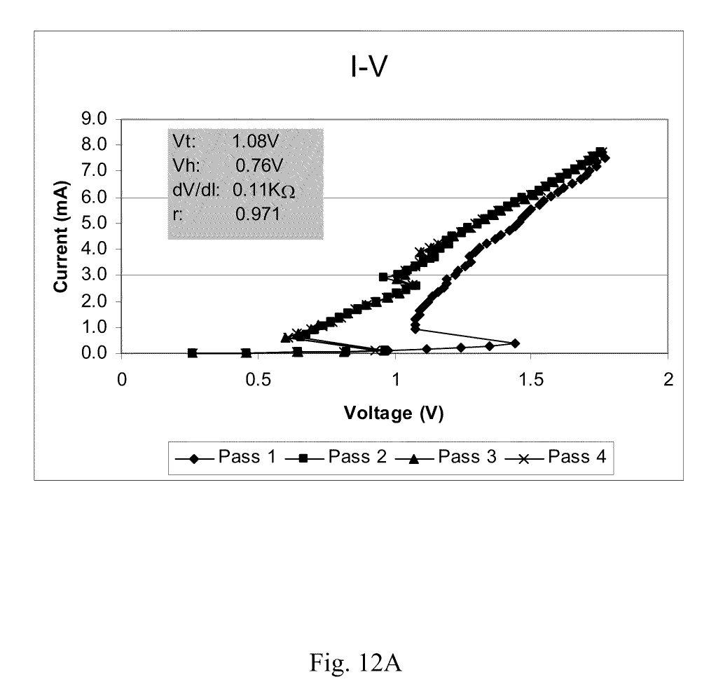

In this example, the beneficial effect of treating an electrode surface on the electrical properties of an active material device is demonstrated. The device used in this example was large-diameter pore device 500 shown in FIG. 11. Device 500 included substrate 505 having an oxide surface 510. A composite lower electrode was formed on oxide surface 510. The composite lower electrode included conductive TiN layer 515 and conductive carbon layer 520. Dielectric (oxide) material 525 was formed on carbon layer 520 and opening 530 was formed in dielectric material 525. The diameter of opening 530 was approximately 890 nm. Opening 530 exposed a portion 535 of the surface of carbon layer 520. Active material 540 was formed over dielectric material 525 and exposed surface 535. Active material 540 was a phase-change alloy denominated “3405” and had the composition Ge₁₈Sb₃₂Te₅₀. Composite upper electrode 545 was formed over active material 540. Composite upper electrode 545 included a 20 Å thick layer of Ti and a 600 Å thick layer of TiN. The structure was completed by forming probe metal layer 550 of Al over upper electrode 545.

Two variants of device 500 were fabricated: an untreated variant and a treated variant. In the untreated variant, the device was fabricated as described above without any treatment of conductive TiN layer 515 or conductive carbon layer 520. Both layers were utilized as deposited in the fabrication of the device. As a result, exposed surface 535 of carbon layer 520 was expected to be rough and textured. In the untreated variant, active 540 was formed directly on untreated exposed surface 535. In the treated variant, the device was fabricated as described above with treatment of both conductive TiN layer 515 and conductive carbon layer 520. The treatment entailed a soft sputter etch that was designed to smooth the surface or each layer. Accordingly, exposed surface 535 of the treated variant of the device was expected to be smooth and uniform with a reduction in roughness relative to exposed surface 535 of the untreated variant of the device. In the treated variant, active material 540 was formed directly on treated exposed surface 535.

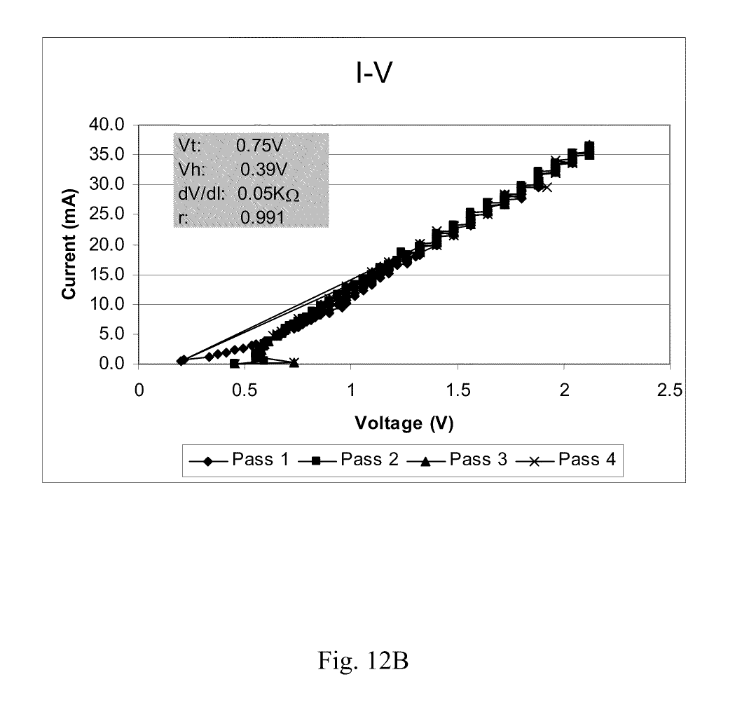

The electrical characteristics of the untreated and treated variants of device 500 were tested. Specifically, the I-V characteristics and R-I characteristics of the two variants of the device were measured to investigate the effect of surface treatment on electrical properties. FIG. 12A shows the I-V response of the untreated variant of device 500 over several cycles of operation. The I-V response of the untreated device shows inconsistent behavior from cycle-to-cycle. Significant variability was observed in both the threshold voltage and dynamic resistance (slope of the conductive branch) of the I-V response. The conductive branch also exhibited random, erratic fluctuations.

An additional point of concern in the I-V response of the untreated device was the large voltage required to initiate switching during the first cycle of operation (“Pass 1”). The threshold voltage of the first cycle of operation approached 1.5V. High initial threshold voltages typically signify the presence of a resistive interface layer between the electrode surface and active material. The resistive interface layer is likely an oxide or other contaminating phase that formed during device processing. As noted hereinabove, the presence of a rough electrode surface may promote the formation of unintended interfacial phases by providing a high surface area and surface bonding states that potentially catalyze or otherwise facilitate the formation of impurity phases.

FIG. 12B shows the I-V response of the treated variant of device 500 over several cycles of operation. The I-V response of the treated device showed a consistent threshold voltage and consistent dynamic resistance during operation. The erratic behavior observed for the threshold voltage and conductive branch in the untreated device was essentially eliminated in the treated device. The initial threshold voltage of the treated device was also much lower than that of the untreated device.

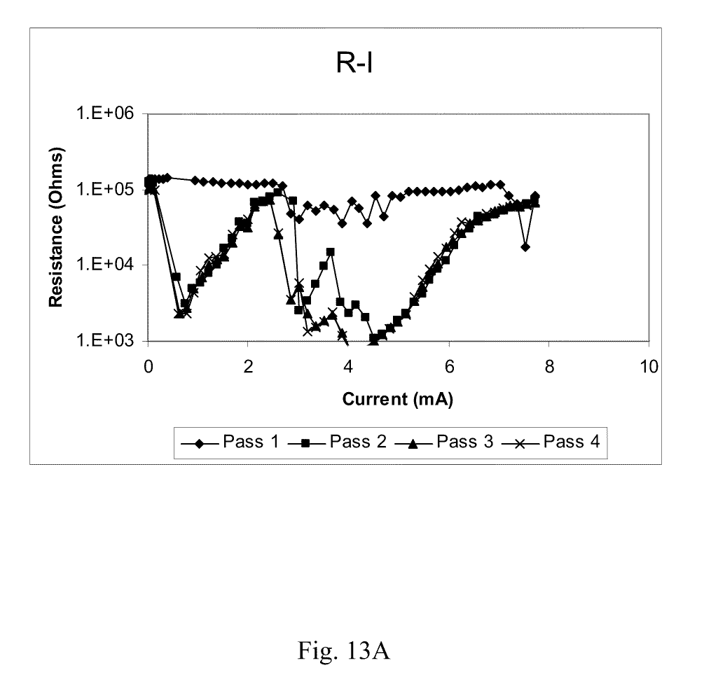

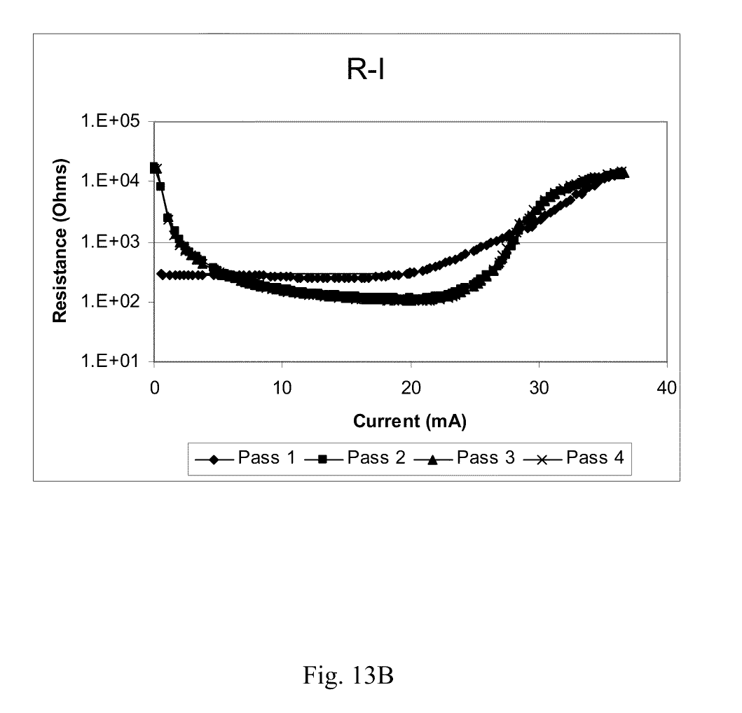

The R-I characteristics of the treated device also showed marked improvements over the R-I characteristics of the untreated device. FIG. 13A shows the R-I response of the untreated variant of device 500 over several cycles of operation. The R-I response of the untreated device was random and irregular. The conditions corresponding to the set transformation were difficult to discern and not reproducible. Numerous fluctuations in resistance with current were also observed. Also, the initial resistance of the device during the initial cycle of operation (“Pass 1”) was over 100 kΩ. The high initial resistance is consistent with the presence of a resistive interface layer.

The R-I response of the treated device shown in FIG. 13B, in contrast, was smooth and reproducible. The conditions corresponding to the set and reset transformations were well-defined and stable. The initial resistance of the first cycle of operation (“Pass 1”) was ˜300Ω and indicated the absence of a resistive interfacial layer in the treated device.

The results of this example show that treatment of the electrode surface to reduce roughness leads to improved device operation. Both the I-V and R-I characteristics of the device were more consistent and reproducible in variants of the device in which the electrode surface in direct contact with the active material was treated to reduce roughness.

Those skilled in the art will appreciate that the methods and designs described above have additional applications and that the relevant applications are not limited to those specifically recited above. Also, the present invention may be embodied in other specific forms without departing from the essential characteristics as described herein. The embodiments described above are to be considered in all respects as illustrative only and not restrictive in any manner.

We claim:

1. A method of forming an electrical device comprising:
providing a first conductive material;
reducing the roughness of the surface of said first conductive material; and
forming a dielectric material in direct contact with said reduced-roughness conductive surface.

2. The method of claim 1, wherein said first conductive material comprises a metal alloy or metal nitride.

3. The method of claim 1, wherein said first conductive material comprises Ti, W, Al, Cu or Mo.

4. The method of claim 3, wherein said first conductive material further comprises N.

5. The method of claim 1, wherein said first conductive material comprises C.

6. The method of claim 1, wherein said reducing roughness includes an etch.

7. The method of claim 6, wherein said etch includes a chemical etch.

8. The method of claim 6, wherein said etch includes sputtering.

9. The method of claim 8, wherein said sputtering occurs in the presence of nitrogen or argon.

10. The method of claim 8, wherein the sputtering power density is less than 0.25 W/cm².

11. The method of claim 8, wherein the sputtering power density is less than 0.20 W/cm².

12. The method of claim 8, wherein the sputtering power density is less than 0.15 W/cm².

13. The method of claim 10, wherein the time of sputtering is less than 15 minutes.

14. The method of claim 10, wherein the time of sputtering is less than 10 minutes.

15. The method of claim 10, wherein the time of sputtering is less than 5 minutes.

16. The method of claim 1, further comprising:
forming an opening in said dielectric material, said opening exposing said reduced roughness surface.

17. The method of claim 16, further comprising:
forming an electrically-active material in said opening

18. The method of claim 17, wherein said electrically-active material is formed in direct contact with said exposed reduced roughness surface.

19. The method of claim 18, wherein said electrically-active material is in direct contact with all of said exposed reduced roughness surface.

20. The method of claim 17, wherein said electrically-active material comprises an electrical memory material.

21. The method of claim 20, wherein said electrically-active material is selected from the group consisting of variable resistance materials, resistive random access materials, phase-change materials, and chalcogenide materials.

22. The method of claim 20, wherein said electrically-active material comprises an electrical switching material.

23. The method of claim 22, wherein said electrical switching material comprises an Ovonic threshold switching material or a chalcogenide switching material.

24. The method of claim 17, further comprising forming a second conductive material over said electrically-active material.

25. The method of claim 1, wherein said providing first conductive material comprises providing a first conductive layer and a second conductive layer.

26. The method of claim 25, wherein said first conductive layer comprises a metal or metal alloy and said second conductive layer comprises C.

27. The method of claim 25, wherein said reducing roughness includes reducing the roughness of the surface of said first conductive layer and reducing the roughness of the surface of said second conductive layer.
